(19) United States
(12) Patent Application Publication
(10) Pub. No.: US 2005/0237067 A1
(43) Pub. Date: Oct. 27, 2005

(54) Arrangement and method for detection and localization of short circuits in membrane electrode arrangements

(75) Inventors: Cornelius Haas, Daisendorf (DE); Mathias Boehmisch, Singen (DE)

Correspondence Address: DAVIDSON, DAVIDSON & KAPPEL, LLC, 485 SEVENTH AVENUE, 14TH FLOOR, NEW YORK, NY, 10018, US

(73) Assignee: DaimlerChrysler AG, Stuttgart (DE)

(21) Appl. No.: 11/108,936

(22) Filed: Apr. 19, 2005

(30) Foreign Application Priority Data
Apr. 22, 2004 (DE) 10 2004 019 475.0

(51) Int. Cl. G01R 31/00

(52) U.S. Cl. 324/501; 324/537

(57) ABSTRACT

An arrangement for non-destructive detection and localization of short circuits in a membrane electrode arrangements (MEA), that includes the following components: a) a sample holder for holding and positioning an MEA; b) means for making electrical contact with an MEA so that an electrical voltage can be applied to the MEA; c) means for detection of position-resolved data via the thermal radiation from a body, which means can be arranged at a distance, which can be predetermined, from the sample holder and can make electronic contact with means for evaluation of the detected data. In addition a method for non-destructive detection and localization of short circuits in an MEA.

Priority is claimed to German Patent Application No. DE 10 2004 019 475.0, filed on Apr. 22, 2004, the entire disclosure of which is incorporated by reference herein.

The present invention relates to an arrangement for detecting and localizing a short circuit in a membrane electrode arrangement, in a non-destructive manner. The invention also relates to a use for this arrangement, and to a method for non-destructive detection of such short circuits.

### BACKGROUND

Arrangements, methods and uses such as these may be used commercially, for example, in the technical field of material testing of components for electrochemical cells.

Fundamentally, electrochemical cells are subdivided into electrolytic cells and galvanic elements. Spontaneous electrochemical reactions take place at electrodes in the galvanic elements, with electric current being produced, while these reactions are necessarily reversed, with electric current being supplied, in electrolytic cells.

Fuel cells are a special type of galvanic element. A fuel cell is an apparatus for energy conversion, which highly efficiently converts chemical energy, which is stored in a fuel, to electrical energy. The reaction materials which are required for the electrochemical reaction that takes place in this case are supplied continuously and separately to the fuel cell. The reaction products are likewise converted and transported away continuously. Fuel cells can themselves be subdivided into various types. For example, fuel cells are distinguished by the form of their electrolyte into phosphoric acid fuel cells (PAFCs for short), alkaline fuel cells (AFCs for short), solid oxide fuel cells (SOFCs for short), melted carbonate fuel cells (MCFCs for short) and polymer electrolyte membrane fuel cells (PEMFCs for short).

Both galvanic elements and electrolytic cells have a number of identical or at least similar components. The invention will be explained in the following text using the example of a PEMFC.

The fundamental design of a PEMFC is as follows. The PEMFC contains a membrane electrode arrangement (MEA for short), which is formed from an anode, a cathode and a PEM, which is arranged between them, as the electrolyte. The MEA is itself in turn arranged between two separator plates, with one separator plate normally having channels for the distribution of fuel, and the other separator plate having channels for the distribution of oxidant, and with the channels facing the MEA. The electrodes, anode and cathode, are generally in the form of gas diffusion electrodes (GDEs for short). These have the function of carrying away the electric current which is produced during the electrochemical reaction (for example, 2H2→O2→2H2O) and allowing the reaction materials, educts and products, to diffuse through. A GDE comprises at least one gas diffusion layer (GDL for short). A catalyst layer is arranged between the GDE and the PEM, and the electrochemical reaction takes place on it. A PEMFC may have further components which are known in principle to those skilled in the art, for example means for cooling, sealing means, ports and the like.

Fuels and oxidants are used as reaction materials. Gaseous reaction materials are generally used, for example H2 or a gas containing H2 (for example reformate gas) as the fuel, and O2 or a gas containing O2 (for example air) as the oxidant. The expression reaction materials means all materials which are involved in the electrochemical reaction, that is to say including reaction products such as H2O.

For correct operation of a fuel cell, it is important for its electrode areas (cathode area and anode area) to be fluidically isolated from one another and not to be in direct electrical contact (the anode and cathode are, of course, indirectly in contact with one another via an electrical conductor when a circuit is closed—however this is not meant in this case). Nevertheless, if the anode and cathode are in electrical contact, for example as a result of a fault caused during manufacture, then this can result in an undesirable electrical short circuit (short, for short), which can have a very considerable adverse effect on the operation of the relevant fuel cell. One particularly important component from this point of view is the MEA, whose tasks include the electrical isolation of the anode and cathode. Unfortunately, an MEA is also a highly fragile structure which is easily damaged while being fitted into a fuel cell, and thus may allow short circuits. With regard to the reliability of PEMFCs, this being the aspect which is currently preventing commercial use of PEMFCs on frequent occasions, it would be desirable to be able to reliably detect such short circuits using simple means and in a simple manner.

However, so far, no apparatus and no method are known by means of which such short circuits in MEAs can be found reliably in a simple manner, that is to say can be detected and localized, without the MEA being damaged or even destroyed in the process.

### SUMMARY OF THE INVENTION

An object of the present invention is thus to provide an arrangement for non-destructive detection and localization of short circuits in MEAs.

A further or alternate object of the present invention is to provide a method by means of which short circuits in MEAs can be non-destructively detected and localized.

Another further or alternate object of the present invention is also to propose a use for the arrangement for non-destructive detection and localization of short circuits in MEAs.

A first subject matter of the present invention is accordingly an arrangement for detection and localization of short circuits in membrane electrode arrangements (MEAs), which arrangement comprises the following components:
a sample holder for holding and positioning a sample, with the sample in the present case preferably being an MEA;
means for making electrical contact with the MEA so that an electrical voltage can be applied to the MEA;
means for detection of position-resolved data via the thermal radiation from a body, which means can be arranged at a distance, which can be predetermined, from the sample holder and can make electronic contact with means for evaluation of the detected data.

The present invention is based on the observation that areas of an MEA which are located in the area of a short circuit emit more thermal radiation when a voltage is applied to the MEA, which thermal radiation differs from the average thermal radiation of the MEA, which is otherwise essentially at the ambient temperature. Such short circuits can therefore be detected by suitable means for detection of position-resolved data about the thermal radiation from a body, that is to say they can be detected and localized, without the sample, that is to say the MEA, being damaged in the process.

It is considerably easier to localize a short circuit when the sample holder has a scale, and an MEA can be positioned in a defined manner with respect to this scale. This allows the coordinates of a short circuit in an MEA to be read in a simple manner on the scale. The scale may in this case also be composed of two or more scale elements which, for example, are arranged at right angles to one another.

Short circuits in an MEA can be localized even more easily if the scale is legible in the infra-red band of the electromagnetic spectrum. In this case, the scale can be seen on, for example, an infra-red image, and the coordinates of a short circuit can be determined in a simple manner visually, using the scale. In this case, it is preferable for the scale to be legible in the wavelength band of electromagnetic radiation from 400 nm to 12 μm.

Furthermore, it is advantageous for the means for making electrical contact with an MEA to have at least one terminal, preferably two terminals, which can be electrically conductively clamped to the MEA. This allows the means to be fitted to the MEA, and detached from it again, in a simple manner. In consequence, it is particularly simple to prepare the sample for testing for short circuits.

Another option, which is likewise advantageous, is to use magnets to make electrical contact. In this case, two magnets are preferably positioned opposite one another on the two sides of the MEA, so that a defined mechanical contact force is produced via the mechanical forces at the contact point.

In the case of yet another option, which is likewise advantageous, the means for making electrical contact may also be a mechanical apparatus, for example a robot arm, whose contents can be pressed against the MEA.

In order to improve the electrical conductivity of the means for making electrical contact, at least one of the means may be coated with an electrically highly conductive material. In this case, it may be sufficient to coat only the contact surface between the means and the MEA.

Suitable coatings are composed, for example, of gold, silver, other noble metals, carbon and the like, or combinations thereof. In this case, the primary factor is the quality and long-term contact and/or surface conductivity. This has the advantage that no heat, or only a small amount of heat, is developed, in consequence, at the contact points between, for example, terminals and the MEA. On the other hand, short circuits in the area of the contact points could be concealed by the heat developed there, and could thus remain unnoticed.

For the purposes of the present invention, thermal imaging apparatuses have been found a particularly suitable means for detection of position-resolved data, with thermal infra-red imaging apparatuses and, in particular, infra-red cameras, being preferred. Position resolution has a number of advantages. For example, knowledge of the location of the fault allows direct conclusions to be drawn with respect to manufacture, so that measures can be taken in order to optimize manufacture, and to avoid the faults. As a further measure, the faulty points can be specifically repaired or reprocessed, thus making it possible to reduce or avoid scrap, and thus making it possible to save costs. Subsequent, repeated inspection using the arrangement according to the invention, or a preferred arrangement, makes it possible to decide whether the measures that have been taken were suitable. Furthermore, the arrangement makes it possible to quickly check effects of design changes or process changes on the occurrence of short circuits. This allows faster and more efficient development of components for an MEA and its production methods.

In this case, it is preferable for the means for detection of position-resolved and time-resolved data to be designed to allow photographically imaging data detection. The advantages of photographic imaging are, for example, the high information content. It is thus possible, for example, to use the arrangement to determine the location, extent, number and intensity (electrical conductivity of the short circuit) of the faults.

Particularly in conjunction with digital data detection of the image, the arrangement can be used to carry out automated and standardized test procedures, which can be integrated in production. Faults can be quantified, classified and assessed statistically.

In this case, it is also preferable for the means for detection of position-resolved data to be designed such that they can also detect time-resolved data. One advantage of this is the capability to use the arrangement to localize faults exactly. Furthermore, the faults and hence also the fault causes can be classified considerably more easily.

Time-resolved data may be detected, for example, by the means for detection of position-resolved data (and in this case time-resolved data as well) being designed such that these means can detect data at specific time intervals (time periods) which are matched to the speed of the processes to be observed. In consequence, all data can be associated with a specific time period, with the length of the time period determining the time resolution. In this context, the expression “frame repetition rates” is used, for example, indicating the number of data detection processes per second. A frame repetition rate which is as high as possible is preferable in this case, although the frame repetition rates are subject to limits resulting from what is currently technically feasible. In this context, frame repetition rates of at least 10 Hz are suitable, preferably of at least 50 Hz, further preferably of at least 90 Hz, and in particular of at least 130 Hz.

It is particularly advantageous for the means for detection of position-resolved data to be designed such that data detection can be carried out in real time, with real-time infra-red image data detection being particularly preferable. This makes it possible, for example, to carry out, optimize and to check and document measures which are used to rectify or repair a fault, even on-line during the measurement.

However, infra-red cameras from the company Thermosensoric GmbH have been found to be particularly suitable for this purpose, such as the CMT 384 M IR camera.

A second subject of the present invention is a method for detection and localization of short circuits in membrane electrode arrangements (MEAs), which comprises the following steps:
positioning of an MEA on a sample holder;
alignment of means for detection of position-resolved data via the thermal radiation from a body at a predetermined distance from the sample holder;
application of an electrical voltage to the MEA;
detection of position-resolved data about the MEA;
evaluation of the detected data.

The method makes it possible to detect short circuits in an MEA in a simple manner and with the aid of thermal radiation, without the MEA being damaged or even destroyed in the process.

The applied voltage in this case must, of course, not be so high that the heat developed at the location of the short circuit is so great that the MEA is damaged there. With the means that are commercially available at the moment for detection of position-resolved data, however, very small temperature differences can be detected, so that very small voltages are in principle sufficient to detect a short circuit in this way. Those skilled in the art will have no problems whatsoever in determining a suitable voltage by routine trial and error.

In particular, the temperature differences which can be detected at the moment are, for example, in the range from 0.01 to 0.03° C. Suitable voltages depend on the nature of the short circuits to be detected and on the respective destruction limit of the component to be investigated. In the case of electrode arrangements, they are typically in the range from 0.1 to 20 V, and in the case of MEAs are in particular in the range from 0.1 to 5 V. The voltages may be constant over time, or may vary. In particular, it is also possible to use voltage pulses, for example a square-wave, triangular waveform and needles or the like, or combinations thereof. This has the advantage that the applied voltage can be matched highly flexibly to the respective requirements. Voltage pulses furthermore allow the measurement time to be shortened, since the magnitude of the voltage can be chosen such that it is greater than the voltage above which the MEA would be damaged if the voltage were to be applied as a continuous voltage.

In situations in which the MEA cannot be recorded as an entirety, it is also possible to detect data from two or more areas of the MEA separately on a position-resolved basis, which can then be combined again in a preferred manner for the evaluation of the data.

This allows the method to be flexibly matched to the respective requirements. Combination of the data for evaluation allows, for example, simpler assessment, documentation and archiving of the data, and thus clear statistical assessment of fault frequencies, intensities and levels. This can then in turn be used to control a production process or to speed up a development process.

The procedure for evaluation of the data is preferably to determine the points or areas of the MEA which have greater thermal radiation, which differs from the average thermal radiation of the MEA, in order to detect any short circuits which may be present.

A point such as this is referred to as a hot spot for the purposes of the present invention. This can preferably be localized in a simple manner with the aid of a scale.

In the case of one preferred variant of the method according to the invention, the position-resolved data is detected by photographic imaging, in particular with the aid of an infra-red camera.

In another preferred variant of the method according to the invention, the position-resolved data is also detected on a time-resolved basis.

In this case, frame repetition rates of at least 10 Hz are suitable, preferably of at least 50 Hz, further preferably of at least 90 Hz, and in particular of at least 130 Hz.

It is also preferable for the detection of position-resolved data to be carried out in real time, in particular by means of real-time infra-red image data detection.

Although the invention has been described above using the example of a PEMFC, it can, however, also be applied to other electrochemical cells. A third subject of the present invention is, in consequence, the use of the arrangement as disclosed above for detection and localization of short circuits in components for electrochemical cells.

The components are preferably electrically non-conductive membranes, which are coated with an electrically conductive material on opposite faces.

Components such as these are, for example, membrane electrode arrangements (MEAs), such as those described by way of example above, catalyst-coated membranes (CCMs) and the like.

### BRIEF DESCRIPTION OF THE DRAWINGS

The invention will be explained in more detail in the following text with reference to the drawings, in which:

FIG. 1 shows an arrangement according to the invention;

FIG. 2 shows a sample holder which is suitable according to the invention;

FIG. 3 shows an MEA which is positioned on a sample holder;

FIG. 4 shows means which are suitable according to the invention for making electrical contact (terminals);

FIG. 5 shows an IR image with three short circuits.

### DETAILED DESCRIPTION

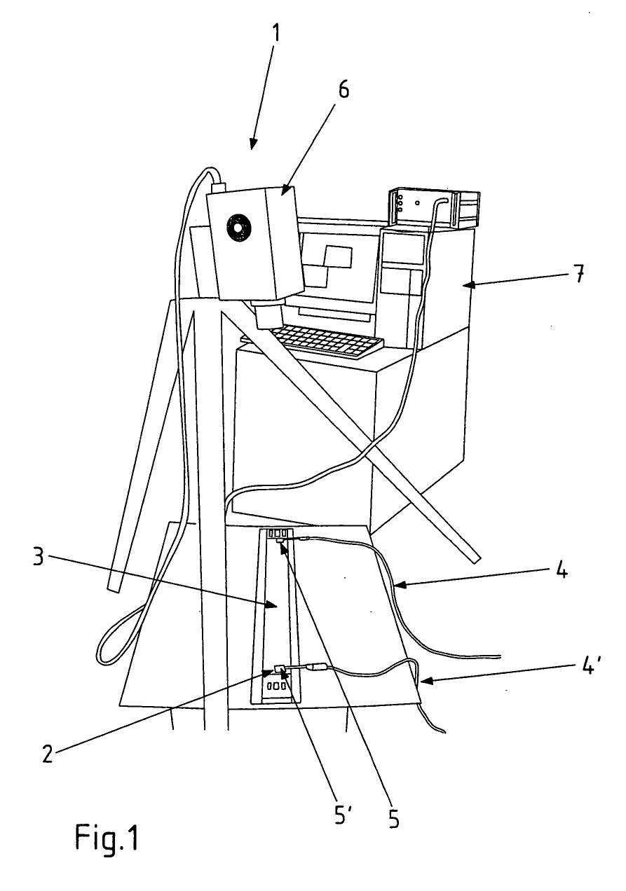

FIG. 1 shows a schematic illustration of an arrangement according to the invention for the detection and localization of short circuits in MEAs (1). The illustration shows a sample holder (2) in which an MEA (3) is held and positioned, means for making electrical contact (4, 4′) between the MEA (3) and two terminals (5, 5′) via which an electrical voltage can be applied to the MEA, and means for detection of position-resolved data via the thermal radiation from a body (6), in this case in the form of an IR camera. The IR camera (6) is arranged at a distance, which can be predetermined, from the sample holder (2) and makes electronic contact with means for evaluation of the detected data (7).

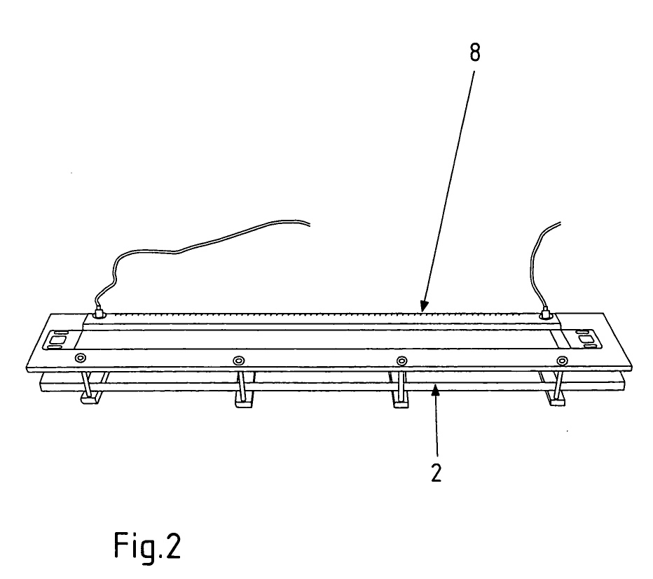

FIG. 2 shows a schematic illustration of a sample holder (2) of an arrangement according to the invention, without an MEA. A scale (8) is illustrated in the upper area of the illustration, with whose aid an MEA can be positioned in the sample holder (2) and which allows localization of short circuits.

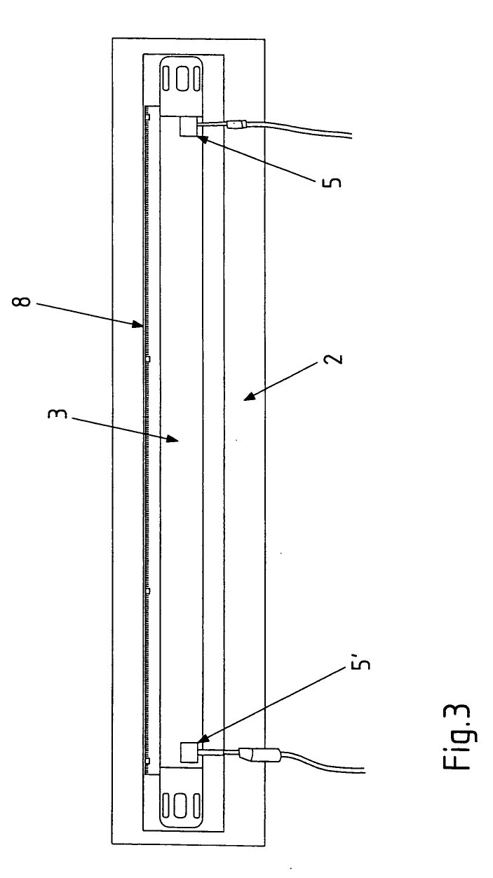

FIG. 3 shows a schematic plan view of a sample holder (2) of an arrangement according to the invention, having an MEA (3) which is held and positioned in it. A scale (8) can also be seen. The left-hand and right-hand parts of the figure each show a terminal (5, 5′), which are part of a means for making electrical contact and with whose aid a voltage can be applied to the MEA (3).

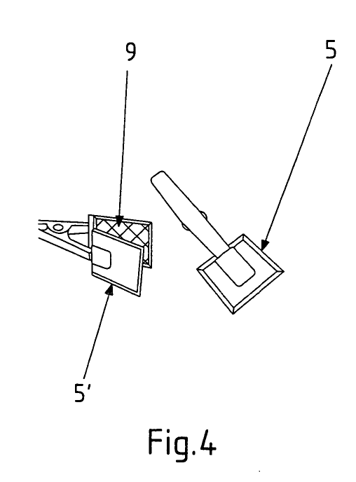

FIG. 4 shows a schematic illustration of electrical contact-making means which are suitable according to the invention. In this case, these are in the form of terminals (5, 5′) which are used to make electrical contact with an MEA. The terminal (5′) has a gold coating (9) which, by virtue of its good electrical conductivity, results in the electrical contact resistance at the point at which contact is made being low, so that little disturbing heat is developed there.

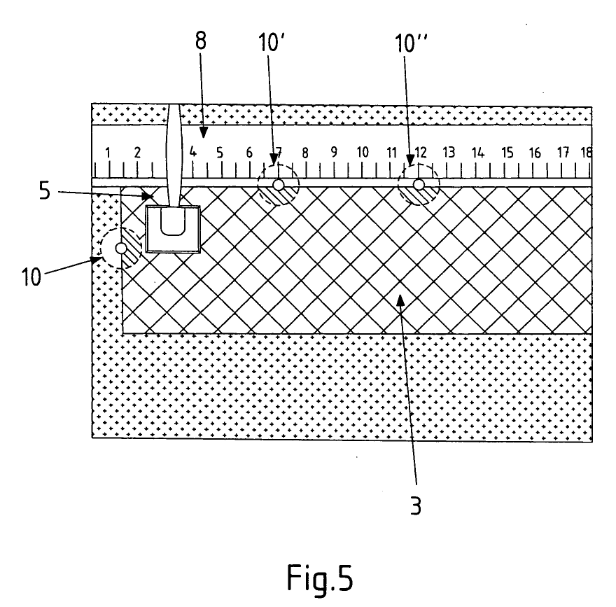

FIG. 5 shows a result of the method according to the invention for detection and localization of short circuits in MEAs, specifically an IR image, in the left-hand part of which an MEA (3) can be seen, with three short circuits (10, 10′, 10″). The short circuits (10, 10′, 10″) are marked by dashed circles, for illustrative purposes. In the illustrated IR image, they can be seen in the form of point, light dots, so-called hot spots. The illustration also shows the IR-visible scale (8) on a sample holder, and a terminal (5). The scale (8) is easily legible, so that the short circuits (10, 10′, 10″) can be localized easily.

1. An arrangement for detection and localization of short circuits in a membrane electrode arrangement (MEA), comprising:
a sample holder configured to hold the MEA in position;
an electrical contact device configured to make electrical contact with the MEA so as to apply electrical voltage to the MEA;
a detector disposed at a predetermined distance from the sample holder and configured to detect a position-resolved data from a thermal radiation of a body; and
a evaluation device disposed in electronic contact with the detector and configured to evaluate the data.

2. The arrangement as recited in claim 1, wherein the sample holder includes a scale, and wherein the MEA is positionable in a defined manner with respect to the scale.

3. The arrangement as recited in claim 2, wherein the scale is legible in the infrared band of the electromagnetic spectrum.

4. The arrangement as recited in claim 1, wherein the electrical contact device includes at least one terminal clampable to the MEA in an electrically conductive manner.

5. The arrangement as recited in claim 1, wherein electrical contact device includes at least one magnet fitted to the MEA in an electrically conductive manner.

6. The arrangement as recited in claim 4, wherein the electrical contact device includes a contact surface coated with an electrically highly conductive material.

7. The arrangement as recited in claim 1, wherein the detector includes a thermal imaging apparatus.

8. The arrangement as recited in claim 1, wherein the detector is configured to allow photographically imaging data detection.

9. The arrangement as recited in claim 1, wherein the detector is configured to detect time-resolved data.

10. The arrangement as recited in claim 9, wherein the detector is configured to provide a frame repetition rate of at least 10 Hz.

11. The arrangement as recited in claim 1, wherein the detector is configured to detect the position-resolved data in real time.

12. A method for detection and localization of short circuits in a membrane electrode arrangement (MEA), the method comprising:
positioning the MEA on a sample holder;
aligning a detector at a predetermined distance from the sample holder, the detector configured to detect position-resolved data from a thermal radiation of a body;
applying an electrical voltage to the MEA;
detecting position-resolved and time-resolved data from the MEA; and
evaluating the detected data.

13. The method as recited in claim 12, wherein the detecting is performed separately from at least two areas of an MEA.

14. The method as recited in claim 13, further comprising combining the separately detected, position-resolved data before the evaluating.

15. The method as recited in claim 12, wherein the evaluating includes determining an area of the MEA having a higher thermal radiation than an average thermal radiation of the MEA to be a hot spot so as to detect the presence of short circuits.

16. The method as recited in claim 15, further comprising localizing the hot spot using a scale.

17. The method as recited in claim 12, wherein the detecting is performed using photographic imaging.

18. The method as recited in claim 12, wherein the detecting of the position-resolved and time-resolved data is performed at a frame repetition rate of at least 10 Hz.

19. The method as recited in claim 12, wherein the position-resolved data is detected in real time.

20. The arrangement as recited in claim 1, wherein the MEA is part of an electrochemical cell.

21. The method as recited in claim 12 wherein the MEA is part of an electrochemical cells.

22. The method as recited in claim 21, wherein the MEA includes an electrically non-conductive membrane coated on opposite faces with an electrically conductive material.

23. The method as recited in claim 21 the MEA includes a catalyst-coated membrane (CCM).
